(19) United States
(12) Patent Application Publication
(10) Pub. No.: US 2019/0304805 A1
(43) Pub. Date: Oct. 3, 2019

(54) ELECTRONIC DEVICE AND METHOD FOR MANUFACTURING THE SAME

(71) Applicant: Intel Corporation, Santa Clara, CA (US)

(72) Inventors: Jiongxin Lu, Chandler, AZ (US); Aravindha Antoniswamy, Phoenix, AZ (US); Jinlin Wang, Chandler, AZ (US); Ashutosh Srivastava, Chandler, AZ (US)

(21) Appl. No.: 15/941,809

(22) Filed: Mar. 30, 2018

(51) Int. Cl. H01L 21/48; H01L 23/498

(52) U.S. Cl. CPC H01L 21/4867; H01L 23/49816; H01L 21/4853

(57) ABSTRACT

An electronic package including a substrate. The substrate includes a first solder material that is applied adjacent a periphery of the substrate. The substrate also includes a second solder material having properties different than the first solder material that is applied adjacent a periphery of a keep in zone of the substrate.

### TECHNICAL FIELD

This document pertains generally, but not by way of limitation, to manufacturing electronic devices. More specifically, this document pertains to providing improved interconnections when forming electronic devices.

### BACKGROUND

Electronic devices typically include an electronic package secured to a motherboard. Manufacturing electronic packages for electronic devices such as computing devices involves rigorous manufacturing processes that involve placing, or connecting electronic components together to establish mechanical and electrical connections. Such electronic components include mother boards, integrated circuits (ICs), chips, memory devices, modern processors, such as a central processing unit (CPU), a graphics processing unit (GPU), advanced processing unit (APU), or combinations thereof, and the like.

When electronic components are manufactured, numerous electrical and mechanical characteristics are considered to create a viable product. Characteristics include, but are not limited to, physical damage, mechanical vibrations, thermal properties, electrical properties such as electric and magnetic fields, electrostatic discharge, package form and size, product loading, power delivery, signal integrity, and the like. These characteristics may be improved by not only improving individual components, but also by improving mechanical and electrical connections between the electronic components.

One manner of interconnect is to utilize a ball grid array (BGA) of solder balls placed on solder pad elements. When connection between two electronic components is desired reflow of the solder balls is provided between the two components to form a joint, or electrical and mechanical connection between the devices. Typically, a paste material is applied to the solder pad elements to provide hold back forces on solder ball elements to maintain sufficient ball attach yield for a desired interconnection. In order to avoid misplaced solder and bridging, techniques have been developed, such as stencil printing, to apply the paste material to the pad elements that minimizes misplacing of the paste material. Still, techniques such as stencil printing require significant board space to be used during the printing process.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a side plan view of a populated motherboard in accordance with an example embodiment.

FIG. 2 is a top plan view of an interface surface of an electronic package in accordance with an example embodiment.

FIG. 3 is a top plan view of an interface surface of an electronic package in accordance with an example embodiment.

FIG. 4 is a top plan view of an interface surface of an electronic package in accordance with an example embodiment.

FIG. 5 is a top plan view of an interface surface of an electronic package in accordance with an example embodiment.

FIG. 6 is a block flow diagram of a method of manufacturing a populated motherboard in accordance with an example embodiment.

FIG. 7 is a block diagram of example devices in accordance with an example embodiment.

### DETAILED DESCRIPTION

When forming electronic devices, such as computing devices, micro-computing devices and the like, the interconnection between different electronic components to a board, such as a motherboard, is key to providing a quality end product. Typically, electronic devices such as integrated circuits (ICs), chips, chip sets, memory devices, modern processors, such as a central processing unit (CPU), a graphics processing unit (GPU), advanced processing unit (APU), or combinations thereof, and the like are sold individually as a unit to a manufacturer that then connects numerous components to a motherboard for a final product.

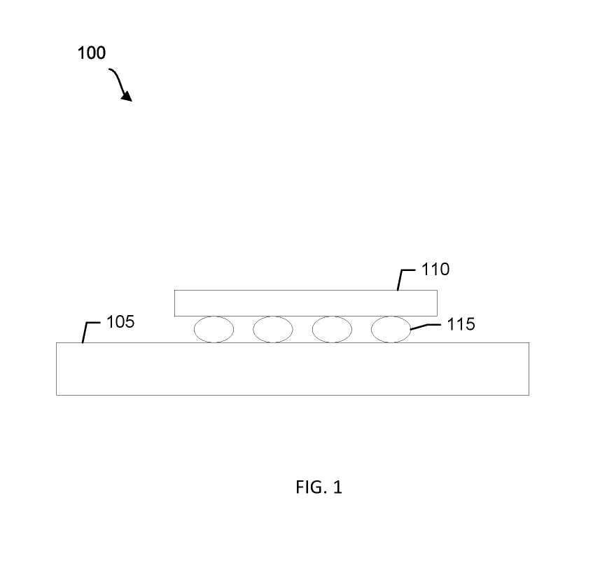

FIG. 1 illustrates an electronic device 100 that includes a motherboard 105 that is interconnected to an electronic package 110 via a solder elements 115. The motherboard 105 is interconnected to the electronic package 110 utilizing manufacturing techniques described herein. The electronic package 110 may include any electronic devices, including but not limited to integrated circuits (ICs), chips, chip sets, memory devices, modern processors, such as a central processing unit (CPU), a graphics processing unit (GPU), advanced processing unit (APU), or combinations thereof, and the like.

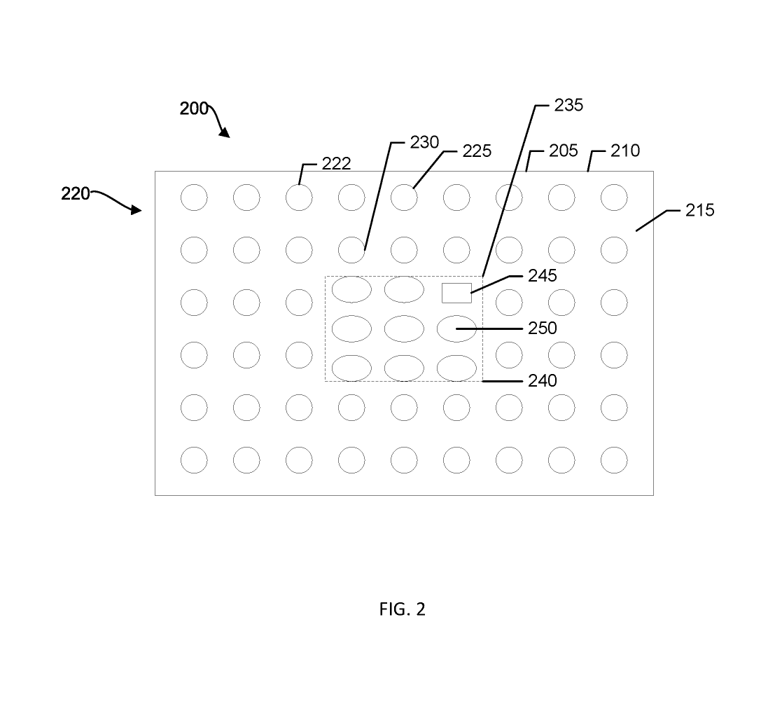

FIG. 2 illustrates a first stage of a manufacturing process utilized to form an electronic package 200 for interconnection with a motherboard. In one example, the electronic package 200 is the electronic package 110 of FIG. 1. In FIG. 2, a substrate 205 is provided with solder mask. The substrate 205 includes a periphery 210 surrounding an interconnect surface 215 that interconnects with a motherboard. An array of solder resist (or mask) openings 220 are spread across the interconnect surface 215. In an example, the solder resist openings 220 are evenly spaced in relation to one another. The solder resist openings 220 expose solder pad elements 222 used for interconnection with electronic components and the motherboard.

The solder pad elements 222 include a set of outer solder pad elements 225 extending from adjacent the periphery 210 of the substrate 205 to a set of inner solder pad elements 230 surrounding and adjacent to a periphery 235 of a keep in zone (KIZ) 240. In this manner, the inner solder pad elements 230 are on the substrate 205 between the outer solder pad elements 225 and the periphery 235 of the keep in zone 240. The keep in zone 240 in an example is centrally located area that receives electronic components 245. The electronic components 245 may include capacitors, resistors, transistors, and the like. The components 245 within the keep in zone are referred to as land-side components. Within the keep in zone 240, electronic components 245 are received by keep in zone solder pads 250 for connection to the substrate 205.

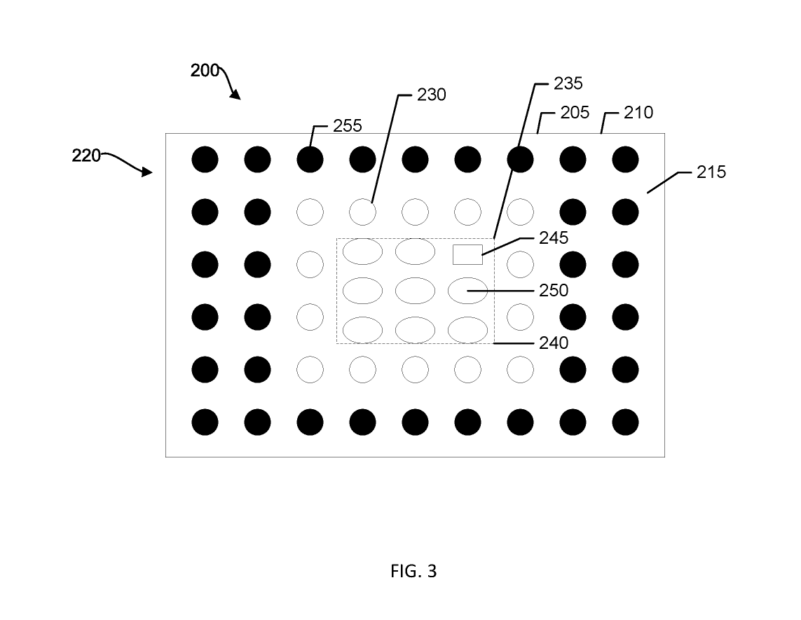

FIG. 3 illustrates a manufacturing stage subsequent to the manufacturing stage illustrated in FIG. 2 for manufacturing the electronic package 200. In FIG. 3, a first solder material 255 has been applied to the outer set of solder pad elements 225, including adjacent the periphery 210 of the substrate 205 using a first application process. In an example, the first solder material is a flux that at elevated soldering temperatures removes oxidation, improving soldering connections. In yet another example, the first solder material is a solder paste that adheres to the solder pad elements and at elevated soldering temperatures melts to form a mechanical and electrical bond during the soldering process. Alternatively, the first solder material is formed having properties of both solder paste and flux to both improve tackiness and still remove oxides during reflow. In another example, the first solder material 255 is applied utilizing a stencil printing process. While the electronic components 245 are illustrated as already connected within the keep in zone 240, such land side components may be connected in a subsequent process.

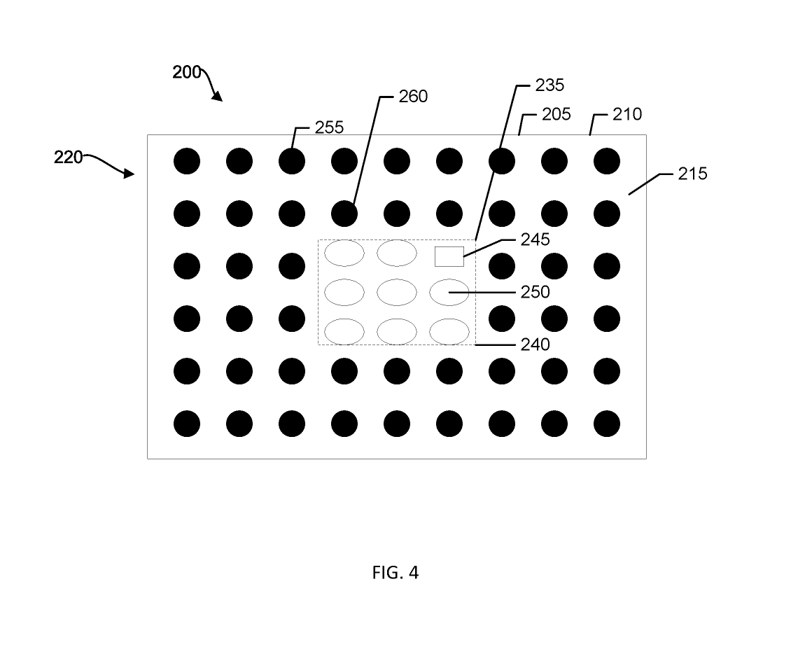

FIG. 4 illustrates a manufacturing stage subsequent to the manufacturing stage illustrated in FIG. 3 for manufacturing the electronic package 200. In FIG. 4, a second solder material 260 has been applied to the inner set of pad elements 230 adjacent the periphery 235 of the keep in zone 240 utilizing a different manufacturing process than was utilized to apply the first solder material 255. In an example, the second solder material 260 is a solder paste having the properties different than the properties of the first solder material 255. These properties may include chemical properties, mechanical properties, thermal properties, and the like. In another example, the second solder material has properties that are described herein. In yet another example, the manufacturing process used to apply the second solder material 260 is a solder paste jetting process.

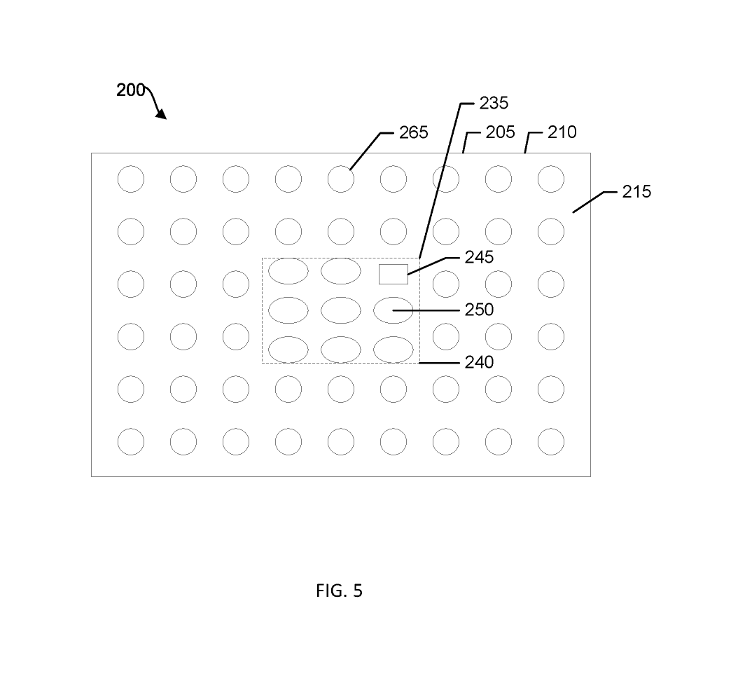

FIG. 5 illustrates a manufacturing stage subsequent to the manufacturing stage illustrated in FIG. 4 for manufacturing the electronic package 200. Specifically, solder balls 265 are placed onto the substrate 205 in preparation for reflow. The solder balls 265 are placed on the set of outer solder pad elements 225 and the set of inner solder pad elements 230. Therefore, for the set of outer pad elements 225 receiving the first paste material 255 and the set of inner pad elements 230 receiving the second paste material 260 both receive solder balls 265 used to provide a soldering connection between the electronic component 200 and a motherboard. As a result of the properties of the first paste material 255 and second paste material 260, minimal solder ball movement, including loss of solder balls due to rolling off a pad element is provided.

In an experiment, an electronic package similar to that described in association with the FIGS. 1-5 was provided. After printing a first paste material onto the substrate as described above, different materials were jetted onto inner solder pad elements of the substrate. Properties associated with each paste and jetting performance were recorded to determine the properties required to manufacture a paste capable of being jetted onto the substrate as required by the methodologies described herein.

The first property measured for each paste was Tangent delta, or Tan delta. Where Tan delta=G″/G′ and where G′ is a storage modulus of the paste material, or the elastic portion of viscoelastic behavior, and G″ is a loss modulus of the material, or the viscous portion of viscoelastic behavior. Tan delta for each paste tested was measured by a controlled stress rheometer with 25 mm parallel plates and a 0.5 mm gap. G′ and G″ were obtained from a dynamic strain sweep test at 5 HZ frequency and strain from 0.01 to 10%.

Thus, a correlation exists between Tan delta value, jetting performance, and dot height at room temperature of various paste materials. Specifically, the risk of clogging and the dot height, if the paste is jettable, increases with an increase in the Tan delta value. From the experiment, to avoid clogging of the paste material the Tan delta for the paste needed to be less than 0.45.

A second property measured for different paste materials was shear thinning at shear rates between 1000 and 5000 l/s. This property was measured using a metric based on the thixotropic index referred to as TI* where TI*=log(1000 l/s)/log (100 l/s). This characteristic was measured using a capillary rheometer. Viscosity values were measured using the capillary rheometer and the acceptable range for a parallel plate rheometer was found to be less than 0.65.

Table 1 below shows TI* measurements and Tan delta measurements of the numerous test paste materials. For TI* the best paste material having a TI* of less than 0.45 showed the best results.

| Material | Tan delta | TI* (capillary rheometer) |
|---|---|---|
| I1 | 0.49 | 0.54 |
| I2 | 0.51 | 0.66 |
| S1 | 0.56 | 0.27 |
| S2 | 0.5 | 0.7 |
| SPJI1 | 0.43 | 0.42 |
| SPJS1 | 0.43 | 0.44 |
| SPJS3 | 0.35 | 0.4 |
| SPJS2 | 0.5 | 0.5 |
| P1 | 0.58 | 0.87 |
| P2 | 0.63 | 0.9 |
| P3 | 0.7 | 0.9 |

As provided in reference to Table 1, solder pastes that successfully jetted without clogging of the jetting equipment were determined in the experiment. Specifically, all solder pastes with a Tan delta of less than 0.45 and a TI* of less than 0.45 were successfully jetted from the jetting equipment without clogging.

Similarly, dot height and paste offset of test paste materials having a Tan delta of less than 0.45 and a TI* of less than 0.45 were also recorded in an experiment to verify the jetting performance. Specifically, dot height is an indicator of clogging while paste offset measures how fine the solder paste application may be applied. When measured, such paste materials showed only a 20% variance from a diameter of 250 um. Similarly, the variance of the paste offset was within a 20% variance. Thus, materials having a Tan delta of less than 0.45 and a TI* of also less than 0.45 presented minimal to no clogging and allow for minimal variance in offset, allowing for reduced distances between inner solder resist openings and the keep in zone.

A final property of the paste materials measure was the tackiness value of each paste. Based on the tackiness values measured by the IPC standard methodology, paste materials having a tackiness value of greater than 100 gram force (gf), and enough activity to remove the oxide from a solder pad (Cu-OSP or NiPdAu) provided the best material for jetting.

Thus, in one example the paste material such as second paste material 260 used for jetting as described above is a paste material having a Tan delta less than 0.45, or a TI* of less than 0.45, or a tackiness value greater than 100 gf. In another example, such a paste material presents at least two of a Tan delta less than 0.45, a TI* less than 0.45, and a tackiness value greater than 100 gf. In yet another example, such paste material presents a Tan delta less than 0.45, a TI* less than 0.45, and a tackiness value greater than 100 gf.

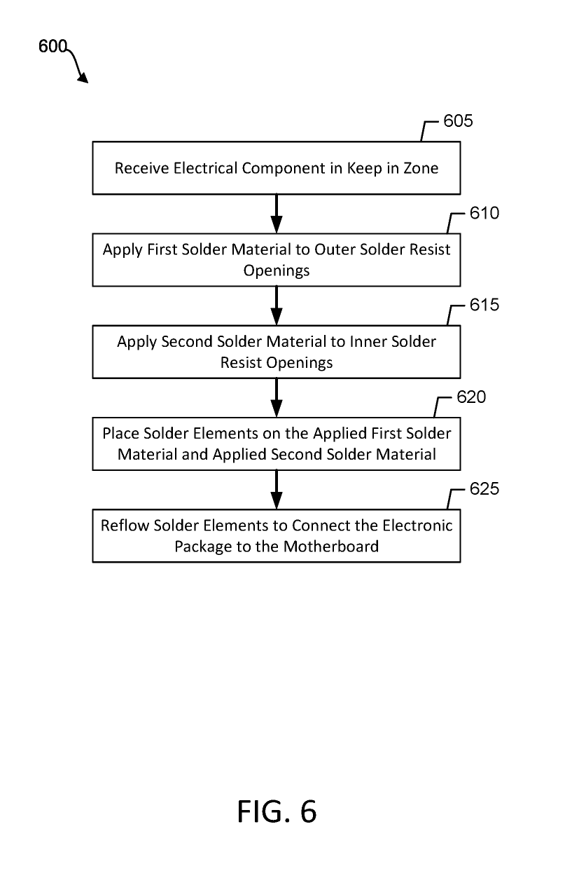

FIG. 6 illustrates a block flow diagram of a method of manufacturing a populated motherboard 600. At 602, an interconnect surface of the electronic package substrate receives at least one electrical component within a keep in zone to provide an electrical connection between the at least one electrical component and electronic package. In an example, the electrical component is a capacitor. In another example, after the at least one electrical component is received, a solder resist layer is applied to the substrate and includes solder resist openings.

At 604, a first solder material is applied to the substrate. The application in one example is in the solder resist opening of a solder resist layer. In another example, the first solder material is applied at spaced locations adjacent a periphery of the substrate. In another example, the first solder material is flux used to receive solder elements such as solder balls and remove oxide from the substrate. In yet another example the first solder material is solder paste. In another example, the first solder material is applied by stencil printing the first solder material onto the substrate.

At 606, a second solder material is applied to the substrate adjacent the periphery of the keep in zone. The second solder material in an example is applied by jetting the material onto the substrate. In another example the second solder material is a solder paste that has a Tan delta of less than 0.45, a TI* of less than 0.45, and a tackiness value greater than 100 gf. In yet another example the second solder material has enough activity to remove the oxide from a solder pad element (Cu-OSP or NiPdAu). In another example the second solder material is a solder paste having a metal loading of less than 60% by weight. In yet another example the second solder material is has minimal residue to prevent bridging. By utilizing techniques such as jetting, improved precision occurs during the application process, allowing a reduction in the space between the second solder material and the periphery of the keep in zone compared to previous manufacturing methodologies. In one embodiment, this distance is in a range between 0.05 mm-0.5 mm.

At 608, solder ball elements are placed on the interconnect surface. Each solder ball element is placed in a respective applied first solder material or second solder material. At 610, the electronic package is placed on the motherboard and reflow of the solder ball elements occurs, providing an electrical and mechanical connection between the electronic package and the motherboard. Because of the properties of the first and second solder materials, desired solder ball element attached yield is achieved.

Because of the use of jetting a second solder material onto the substrate adjacent the periphery of the keep in zone, the space between such solder material and the keep in zone is reduced, minimizing the dimensions of the package on the motherboard. Thus, using this technique, the motherboard similarly may be reduced in size to correspond to the reduced size of the electronic package. By reducing size, end products are similarly reduced in size, or additional electronic components are able to be added to the motherboard to improve functionality. Thus, a fine pitch (in a range between 0.05 mm-0.5 mm) electronic package is provided that has greater warpage tolerance compared to stencil printing methodologies while maintaining solder ball attach yield. Therefore, the method provides an improved manufacturing process for an improved end product.

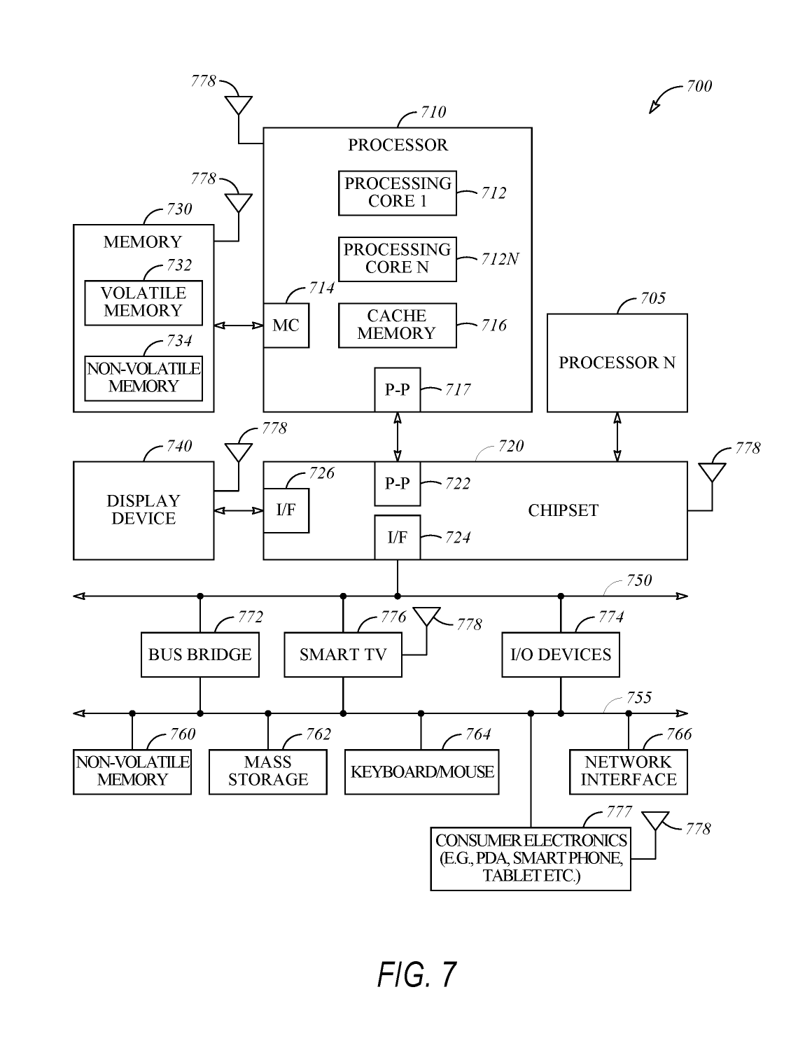

FIG. 7 illustrates a system level diagram, depicting an example of an electronic device (e.g., system) including CPUs and processors, graphics devices, memories, and the like where in one example electronic device 100 is the electronic device of FIG. 7. FIG. 7 is included to show an example of a higher level device application for the packages 200 as described in the present disclosure. In one embodiment, system 700 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 700 is a system on a chip (SOC) system.

In one embodiment, processor 710 has one or more processor cores 712 and 712N, where 712N represents the Nth processor core inside processor 710 where N is a positive integer. In one embodiment, system 700 includes multiple processors including 710 and 705, where processor 705 has logic similar or identical to the logic of processor 710. In some embodiments, processing core 712 includes, but is not limited to, pre-fetch logic to fetch instructions, decode logic to decode the instructions, execution logic to execute instructions and the like. In some embodiments, processor 710 has a cache memory 716 to cache instructions and/or data for system 700. Cache memory 716 may be organized into a hierarchal structure including one or more levels of cache memory.

In some embodiments, processor 710 includes a memory controller 714, which is operable to perform functions that enable the processor 710 to access and communicate with memory 730 that includes a volatile memory 732 and/or a non-volatile memory 734. In some embodiments, processor 710 is coupled with memory 730 and chipset 720. Processor 710 may also be coupled to a wireless antenna 778 to communicate with any device configured to transmit and/or receive wireless signals. In one embodiment, an interface for wireless antenna 778 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 732 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 734 includes, but is not limited to, flash memory, phase change memory (PCM), read-only memory (ROM), electrically erasable programmable read-only memory (EEPROM), or any other type of non-volatile memory device.

Memory 730 stores information and instructions to be executed by processor 710. In one embodiment, memory 730 may also store temporary variables or other intermediate information while processor 710 is executing instructions. In the illustrated embodiment, chipset 720 connects with processor 710 via Point-to-Point (PtP or P-P) interfaces 717 and 722. Chipset 720 enables processor 710 to connect to other elements in system 700. In some embodiments of the example system, interfaces 717 and 722 operate in accordance with a PtP communication protocol such as the Intel® QuickPath Interconnect (QPI) or the like. In other embodiments, a different interconnect may be used.

In some embodiments, chipset 720 is operable to communicate with processor 710, 705N, display device 740, and other devices, including a bus bridge 772, a smart TV 776, I/O devices 774, nonvolatile memory 760, a storage medium (such as one or more mass storage devices) 762, a keyboard/mouse 764, a network interface 766, and various forms of consumer electronics 777 (such as a PDA, smart phone, tablet etc.), etc. In one embodiment, chipset 720 couples with these devices through an interface 724. Chipset 720 may also be coupled to a wireless antenna 778 to communicate with any device configured to transmit and/or receive wireless signals.

Chipset 720 connects to display device 740 via interface 726. Display 740 may be, for example, a liquid crystal display (LCD), a light emitting diode (LED) array, an organic light emitting diode (OLED) array, or any other form of visual display device. In some embodiments of the example system, processor 710 and chipset 720 are merged into a single SOC. In addition, chipset 720 connects to one or more buses 750 and 755 that interconnect various system elements, such as I/O devices 774, nonvolatile memory 760, storage medium 762, a keyboard/mouse 764, and network interface 766. Buses 750 and 755 may be interconnected together via a bus bridge 772.

In one embodiment, mass storage device 762 includes, but is not limited to, a solid state drive, a hard disk drive, a universal serial bus flash memory drive, or any other form of computer data storage medium. In one embodiment, network interface 766 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 7 are depicted as separate blocks within the system 700, the functions performed by some of these blocks may be integrated within a single semiconductor circuit or may be implemented using two or more separate integrated circuits. For example, although cache memory 716 is depicted as a separate block within processor 710, cache memory 716 (or selected aspects of 716) can be incorporated into processor core 712.

### Various Notes & Examples

Example 1 is an electronic package comprising: a substrate; a first solder material applied on the substrate adjacent a periphery of the substrate; a second solder material having properties different than the first solder material applied on the substrate adjacent a periphery of a keep in zone.

In Example 2, the subject matter of Example 1 optionally includes wherein the electronic package is one of a memory device, CPU, GPU, or processor.

In Example 3, the subject matter of any one or more of Examples 1-2 optionally include wherein the first solder material is a flux and the second solder material is a solder paste.

In Example 4, the subject matter of any one or more of Examples 1-3 optionally include wherein the second solder material is a solder paste having a Tangent delta of less than 0.45.

In Example 5, the subject matter of Example 4 optionally includes wherein the solder paste has a thixotropic index of less than 0.45 log(1000 l/s)/log (100 l/s) for shear rates between 1000 and 5000 l/s.

In Example 6, the subject matter of Example 5 optionally includes wherein the solder paste has a tackiness value of at least 100 gram force (gf).

In Example 7, the subject matter of any one or more of Examples 1-6 optionally include wherein the second solder material has metal loading of less than 60% by weight.

In Example 8, the subject matter of any one or more of Examples 1-7 optionally include wherein the keep in zone is centrally located on the substrate.

In Example 9, the subject matter of Example 8 optionally includes wherein the keep in zone has at least one electronic component.

In Example 10, the subject matter of Example 9 optionally includes mm from the second solder material applied adjacent the periphery of the keep in zone.

In Example 11, the subject matter of any one or more of Examples 1-10 optionally include a solder resist layer on the substrate including a first solder resist opening that receives the first solder material and a second solder resist opening that receives the second solder material.

Example 12 is an electronic device comprising: a motherboard; an electronic package coupled to the motherboard comprising: a substrate; a keep in zone on the substrate having an electronic component; a first solder material applied on the substrate adjacent a periphery of the substrate; and a second solder material having properties different than the first solder material and applied on the substrate adjacent a periphery of the keep in zone.

In Example 13, the subject matter of Example 12 optionally includes wherein the electronic package is one of a memory device, CPU, GPU, or processor.

In Example 14, the subject matter of any one or more of Examples 12-13 optionally include wherein the second solder material has a Tangent delta of less than 0.45.

In Example 15, the subject matter of any one or more of Examples 12-14 optionally include a solder resist layer on the substrate including a first solder resist opening that receives the first solder material and a second solder resist opening that receives the second solder material; a first solder ball engaging the first solder material and reflowed to form a first joint between the electronic package and the mother board; and a second solder ball engaging the second solder material and reflowed to form a second joint between the electronic package and the mother board.

Example 16 is a method of manufacturing an electronic package comprising: printing a first solder material on a substrate; jetting a second solder material on the substrate adjacent a keep in zone of the substrate; placing a first solder element on the first solder material; and placing a second solder element on the second solder material.

In Example 17, the subject matter of Example 16 optionally includes wherein the first solder material is a flux and the second solder material is a solder paste.

In Example 18, the subject matter of any one or more of Examples 16-17 optionally include wherein the second solder material is a solder paste having a Tangent delta of less than 0.45.

In Example 19, the subject matter of Example 18 optionally includes wherein the solder paste has a thixotropic index of less than 0.45 (1000 l/s)/log (100 l/s) for shear rates between 1000 and 5000 l/s.

In Example 20, the subject matter of Example 19 optionally includes wherein the solder paste has a tackiness value of at least 100 gram force (gf).

In Example 21, the subject matter of any one or more of Examples 16-20 optionally include wherein the second solder material has metal loading of less than 60% by weight.

In Example 22, the subject matter of any one or more of Examples 16-21 optionally include wherein the step of printing a first solder material on the substrate comprises stencil printing the first solder material on the substrate.

In Example 23, the subject matter of any one or more of Examples 16-22 optionally include placing an electronic component on the substrate in the keep in zone.

In Example 24, the subject matter of Example 23 optionally includes wherein the electronic component is a capacitor.

In Example 25, the subject matter of any one or more of Examples 16-24 optionally include removing oxide from the substrate with the second solder material.

Each of these non-limiting examples may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of“at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

1. An electronic package comprising:
a substrate;
a first solder material applied on the substrate adjacent a periphery of the substrate;
a second solder material having properties different than the first solder material applied on the substrate adjacent a periphery of a keep in zone.

2. The device of claim 1, wherein the electronic package is one of a memory device, CPU, GPU, or processor.

3. The device of claim 1, wherein the first solder material is a flux and the second solder material is a solder paste.

4. The device of claim 1, wherein the second solder material is a solder paste having a Tangent delta of less than 0.45.

5. The device of claim 4, wherein the solder paste has a thixotropic index of less than 0.45 log(1000 l/s)/log (100 l/s) for shear rates between 1000 and 5000 l/s.

6. The device of claim 5 wherein the solder paste has a tackiness value of at least 100 gram force (gf).

7. The method of claim 1 wherein the second solder material has metal loading of less than 60% by weight.

8. The device of claim 1, wherein the keep in zone is centrally located on the substrate.

9. The device of claim 8, wherein the keep in zone has at least one electronic component.

10. The device of claim 9, wherein the electronic component is spaced in a range between 0.05-0.5 mm from the second solder material adjacent the periphery of the keep in zone.

11. The device of claim 1 further comprising:
a solder resist layer on the substrate including a first solder resist opening that receives the first solder material and a second solder resist opening that receives the second solder material.

12. An electronic device comprising:
a motherboard;
an electronic package coupled to the motherboard comprising:
a substrate;
a keep in zone on the substrate having an electronic component;
a first solder material applied on the substrate adjacent a periphery of the substrate; and
a second solder material having properties different than the first solder material and applied on the substrate adjacent a periphery of the keep in zone.

13. The device of claim 12 wherein the electronic package is one of a memory device, CPU, GPU, or processor.

14. The device of claim 12 wherein the second solder material has a Tangent delta of less than 0.45.

15. The device of claim 12 further comprising:
a solder resist layer on the substrate including a first solder resist opening that receives the first solder material and a second solder resist opening that receives the second solder material;
a first solder ball engaging the first solder material and reflowed to form a first joint between the electronic package and the mother board; and
a second solder ball engaging the second solder material and reflowed to form a second joint between the electronic package and the mother board.

16. A method of manufacturing an electronic package comprising:
printing a first solder material on a substrate;
jetting a second solder material on the substrate adjacent a keep in zone of the substrate;
placing a first solder element on the first solder material; and
placing a second solder element on the second solder material.

17. The method of claim 16 wherein the first solder material is a flux and the second solder material is a solder paste.

18. The method of claim 16 wherein the second solder material is a solder paste having a Tangent delta of less than 0.45.

19. The method of claim 18 wherein the solder paste has a thixotropic index of less than 0.45 (1000 l/s)/log (100 l/s) for shear rates between 1000 and 5000 l/s.

20. The method of claim 19 wherein the solder paste has a tackiness value of at least 100 gram force (gf).

21. The method of claim 16 wherein the second solder material has metal loading of less than 60% by weight.

22. The method of claim 16, wherein the step of printing a first solder material on the substrate comprises stencil printing the first solder material on the substrate.

23. The method of claim 16, further comprising:
placing an electronic component on the substrate in the keep in zone.

24. The method of claim 23, wherein the electronic component is a capacitor.

25. The method of claim 16 further comprising, removing oxide from the substrate with the second solder material.
